(19) United States
(12) Patent Application Publication
(10) Pub. No.: US 2006/0013342 A1
(43) Pub. Date: Jan. 19, 2006

(54) Method and apparatus for managing buffer for block deinterleaver in a mobile communication system

(75) Inventors: Jong-Hun Rhee, Suwon-si (KR); Min-Goo Kim, Yongin-si (KR); Su-Yean Kim, Yeonsu-gu (KR)

Correspondence Address: ROYLANCE, ABRAMS, BERDO & GOODMAN, L.L.P., 1300 19TH STREET, N.W., SUITE 600, WASHINGTON,, DC, 20036, US

(73) Assignee: Samsung Electronics Co., Ltd.

(21) Appl. No.: 11/176,193

(22) Filed: Jul. 8, 2005

(30) Foreign Application Priority Data
Jul. 8, 2004 (KR) 2004-53213

(51) Int. Cl. H03D 1/00

(52) U.S. Cl. 375/340

(57) ABSTRACT

A method and apparatus for managing a deinterleaver buffer comprised of a plurality of sub-buffers in a receiver that performs Reed-Solomon (RS) decoding on a frame received from a transmitter via a wireless network for a mobile communication system including a block interleaver used in the transmitter. The method and apparatus set input and output indexes of the received frame, and initial input and output addresses of the deinterleaver buffer for the received frame; input the received frame to the deinterleaver buffer according to the set input address; if deinterleaving for at least one of the sub-buffers has been completed, perform RS decoding on a deinterleaved first sub-buffer; and fill an empty region of other sub-buffers with a newly received frame, after completion of the RS decoding on the deinterleaved first sub-buffer.

### PRIORITY

This application claims the benefit under 35 U.S.C. §119(a) of an application entitled “Method and Apparatus for Managing Buffer for Block Deinterleaver in a Mobile Communication System” filed in the Korean Intellectual Property Office on Jul. 8, 2004 and assigned Ser. No. 2004-53213, the entire content of which is hereby incorporated by reference.

### BACKGROUND OF THE INVENTION

1. Field of the Invention

The present invention relates generally to a method and apparatus for managing a buffer in a receiver for a mobile communication system. In particular, the present invention relates to a method and apparatus for managing a buffer needed for a deinterleaver of a receiver.

2. Description of the Related Art

The mobile communication system has evolved from an early system supporting a voice-oriented service into an advanced system supporting data communication. The mobile communication system is now evolving into a future system capable of supporting a broadcast service along with various data services. The broadcast service is called “Broadcast/Multicast Service (BCMCS)” in a 3^{rd} generation partnership project-2 (3GPP2) group in which Code Division Multiple Access (CDMA) is used. In addition to the BCMCS for a CDMA2000 1x Rev. D standard, BCMCS for a HRPD Rev. A standard, which is another synchronous CDMA standard, also provides various specifications for the broadcast service. In the following description, the BCMCS service for the CDMA standards, including the CDMA2000 1x Rev. D standard and the HRPD Rev. A standard, will be referred to as a “broadcast service.”

The broadcast service provides that broadcast data is transmitted in units of frames each having a period of, for example, 20 ms. The broadcast service can use Reed-Solomon (RS) codes, which are error correction codes well known as outer codes, aside from inner codes such as convolutional codes and turbo codes for channel coding. The CDMA2000 1x Rev. D standard proposes that the RS codes should be used to prevent continuous transmission errors for transmission broadcast data. According to the CDMA2000 1x Rev. D standard, the broadcast service performs RS coding using, for example, 4 sub-buffers, and a selected one of coding rates of 11/16, 12/16, 13/16, and 14/16 can be used for the RS coding. The broadcast data is subjected to block interleaving after the RS coding and inner coding, and then transmitted to a wireless network frame by frame.

A general coding process for the RS codes will now be described in more detail.

FIG. 1 is a block diagram illustrating an internal structure of a transmitter including outer encoders 30a to 30d, which are RS encoders, and an inner encoder 50. With reference to FIG. 1, a brief description will now be made of a general outer and inner coding process.

Referring to FIG. 1, 100320/109440/118560/127,680 input channel bits are provided to a demultiplexer (DEMUX) 10 for 1.28 seconds according to RS coding rates. The demultiplexer 10 demultiplexes the input channel bits, and delivers the demultiplexed channel bits to the outer encoders 30a to 30d. The outer encoders 30a to 30d encode the channel bits with RS codes in a plurality of sub-buffers. The symbols RS-encoded in the sub-buffers are multiplexed by a multiplexer (MUX) 40, and then provided to an inner encoder 50 such as a channel encoder.

FIG. 2 is a diagram illustrating a structure of a buffer for a deinterleaver in a mobile communication system.

Referring to FIG. 2, each of sub-buffers 20a, 20b, 20c and 20d is comprised of 16 frames. Of the 16 frames, k frames are made according to information on the frames on which broadcast data is carried, and the remaining (16−k) frames are parity frames created by RS codes. Herein, kε{11, 12, 13, 14}.

In FIG. 2, (A) represents information order of transmission data before RS coding, (B) represents information order of the transmission data after RS coding, and (C) represents the transmission order of the transmission data after RS coding. Each of the sub-buffers 20a to 20d, or sub-buffers 0-3, respectively, has, for example, 16 frames, and each frame is channel-coded by the inner encoder 50.

The first k frames are information frames in which the input transmission data bits of FIG. 1 are stored in order, and the last (16−k) frames are parity frames generated by RS coding. As shown in (B), (16−k) parity frames are generated from k information frames by RS coding, preparing data of a total of 64 frames. As shown in (C), the 64 frames are transmitted in the order of a first frame, a second frame, and so forth, for the sub-buffers 20a, 20b, 20c and 20d, to be inner coded. Herein, the numbers shown in (C) represent the transmission order of the corresponding frames, and the transmission order is equal to that in the general block interleaving.

Therefore, a receiver of a mobile station using the broadcast service needs a reception buffer that undergoes block deinterleaving, and the reception buffer is basically equal in size to the transmission buffer used in the transmitter. The buffers have a 64-frame size. The receiver needs additional output buffers taking into account the time required for decoding RS-coded reception frames. A brief description will now be made of a method for managing a buffer in the receiver.

In the receiver, all of the 64 data frames are received and inner-decoded independently through an inner decoder, and the decoded frames are all stored in 4 sub-buffers. Thereafter, the receiver performs RS decoding on the 4 sub-buffers individually, thereby correcting data errors. A host of the receiver reads the RS-decoded frames in each of the sub-buffers in the order of the sub-buffers. In the empty sub-buffers, newly received frames are stored in regular order. If all of the 64 data frames are received, the above process is repeated.

As shown in FIG. 2, because the sub-buffers are independently subject to RS coding, the receiver can perform RS decoding before all of the 4 sub-buffers are fully filled. If a frame #60 is received at the receiver, the receiver can perform RS decoding on a sub-buffer #0 20a because the sub-buffer #0 20a is full. Similarly, a sub-buffer #1 20b can undergo RS decoding when a frame #61 is received, and a sub-buffer #2 20c can undergo RS decoding when a frame #62 is received. In this manner, the sub-buffers can partially undergo the RS decoding before they are fully filled with the 64 frames. After each RS decoding, data in the corresponding sub-buffer can be moved to an output buffer so that the data can be delivered to the host. This method contributes to a reduction in size of a deinterleaver buffer of the receiver, and can be applied to a decoder that can perform decoding before its deinterleaver is fully filled with data. Therefore, an output buffer is used for the decoded data to secure a time required by the host for reading data, and this requires a process of copying data. However, the output buffer is not required if a size of the deinterleaver buffer is increased by a size of the output buffer. That is, the unnecessary data copying process can be removed by placing the output buffer in the deinterleaver buffer.

### SUMMARY OF THE INVENTION

It is, therefore, an object of the present invention to provide a method and apparatus for efficiently managing a deinterleaver buffer by designing the deinterleaver buffer such that a size of the deinterleaver buffer is less than a size of a block interleaver used in a transmitter.

It is another object of the present invention to provide a deinterleaver buffer management method and apparatus for avoiding an unnecessary data copying process by placing an output buffer for providing the time required by a host to read decoded data in the deinterleaver buffer.

According to one aspect of the present invention, there is provided a method for managing a deinterleaver buffer using one deinterleaver table in a mobile communication system, the method comprising the steps of making the deinterleaver buffer in a size smaller than a size of the block interleaver; receiving data interleaved in a predetermined size, and storing frames of the data in the deinterleaver buffer in regular order; deinterleaving the frames of the data stored in the deinterleaver buffer; separately decoding the deinterleaved frames in sub-buffers of the deinterleaver buffer; and preparing to deliver a decoded frame in a position with a first buffer index to a host every frame, delivering a decoded frame in a position with a second buffer index to the host, and storing a new frame in a sub-buffer empted due to the delivery of the decoded frame in the position with the second buffer index.

According to another aspect of the present invention, there is provided a method for managing a deinterleaver buffer using one deinterleaver table in a mobile communication system, the method comprising the steps of making the deinterleaver buffer in a size smaller than a size of the block interleaver; receiving data interleaved in a predetermined size, and storing frames of the data in the deinterleaver buffer; deinterleaving the frames of the data stored in the deinterleaver buffer; and separately decoding the deinterleaved frames in sub-buffers of the deinterleaver buffer, delivering the decoded frames to a host, and storing new frames in sub-buffers emptied due to the delivery of the decoded frames to the host.

According to further another aspect of the present invention, there is provided a method for managing a deinterleaver buffer using two deinterleaver tables in a mobile communication system, the method comprising the steps of making the deinterleaver buffer in a size smaller than a size of the block interleaver; receiving odd-numbered data interleaved in a predetermined size, and storing frames of the received odd-numbered data in the deinterleaver buffer in a first deinterleaver table; receiving even-numbered data interleaved in a predetermined size, and storing frames of the received even-numbered data in the deinterleaver buffer in a second deinterleaver table; deinterleaving the frames of the data stored in the deinterleaver buffer; separately decoding the deinterleaved frames in sub-buffers of the deinterleaver buffer; preparing to deliver a decoded frame in a position with a first buffer index to a host every frame, delivering a decoded frame in a position with a second buffer index to the host, and storing a new frame in a sub-buffer emptied due to the delivery of the decoded frame in the position with the second buffer index; and detecting an empty first buffer index from the second deinterleaver table in the second buffer region, writing information on the empty buffer index in a position of its buffer, and storing the position information in its respective deinterleaver table.

According to still another aspect of the present invention, there is provided an apparatus for managing a deinterleaver buffer in a mobile communication system, the apparatus comprising a deinterleaver for making the deinterleaver buffer in a size smaller than a size of a block interleaver, for receiving data interleaved in a predetermined size, for storing frames of the data in the deinterleaver buffer in regular order, and for deinterleaving frames of the data stored in the deinterleaver buffer; and a decoder for separately decoding frames in sub-buffers of the deinterleaver buffer, wherein the deinterleaver delivers the decoded frames to a host, and stores new frames in the sub-buffers emptied due to the delivery of the decoded frames.

### BRIEF DESCRIPTION OF THE DRAWINGS

The above and other objects, features and advantages of the present invention will become more apparent from the following detailed description when taken in conjunction with the accompanying drawings in which:

FIG. 1 is a block diagram illustrating an internal structure of a general transmitter including outer encoders and an inner encoder;

FIG. 2 is a diagram illustrating a structure of a deinterleaver buffer in a mobile communication system;

FIG. 3 is a diagram illustrating indexes representing 64 frames in a mobile communication system according to an embodiment of the present invention;

FIG. 4 is a diagram illustrating an exemplary method for deinterleaving data stored in a buffer in a mobile communication system according to an embodiment of the present invention;

FIG. 5 is a diagram illustrating another exemplary method for deinterleaving data stored in a buffer in a mobile communication system according to an embodiment of the present invention;

FIG. 6 is a flowchart illustrating an operation of managing a deinterleaver buffer according to an embodiment of the present invention;

FIG. 7 is a diagram illustrating conversion of a buffer address table by a deinterleaver according to an embodiment of the present invention;

FIGS. 8 and 9 are diagrams illustrating examples of C-language programming code used for a triangular permutation method according to embodiments of the present invention;

FIG. 10 is a diagram illustrating an example of a buffer with a 62-frame size in a deinterleaver for a broadcast service system according to an embodiment of the present invention; and

FIG. 11 is a flowchart illustrating an operation of managing a deinterleaver buffer according to an embodiment of the present invention.

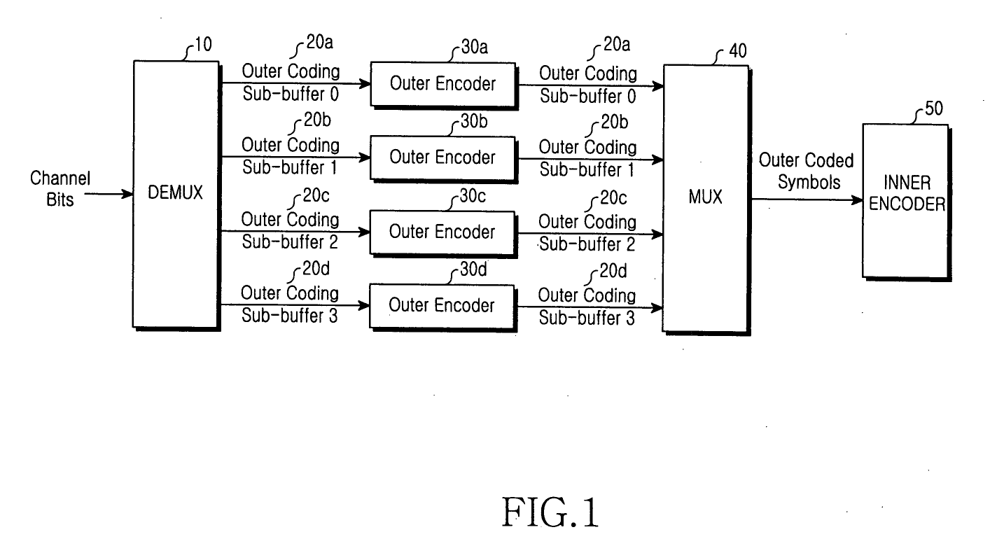

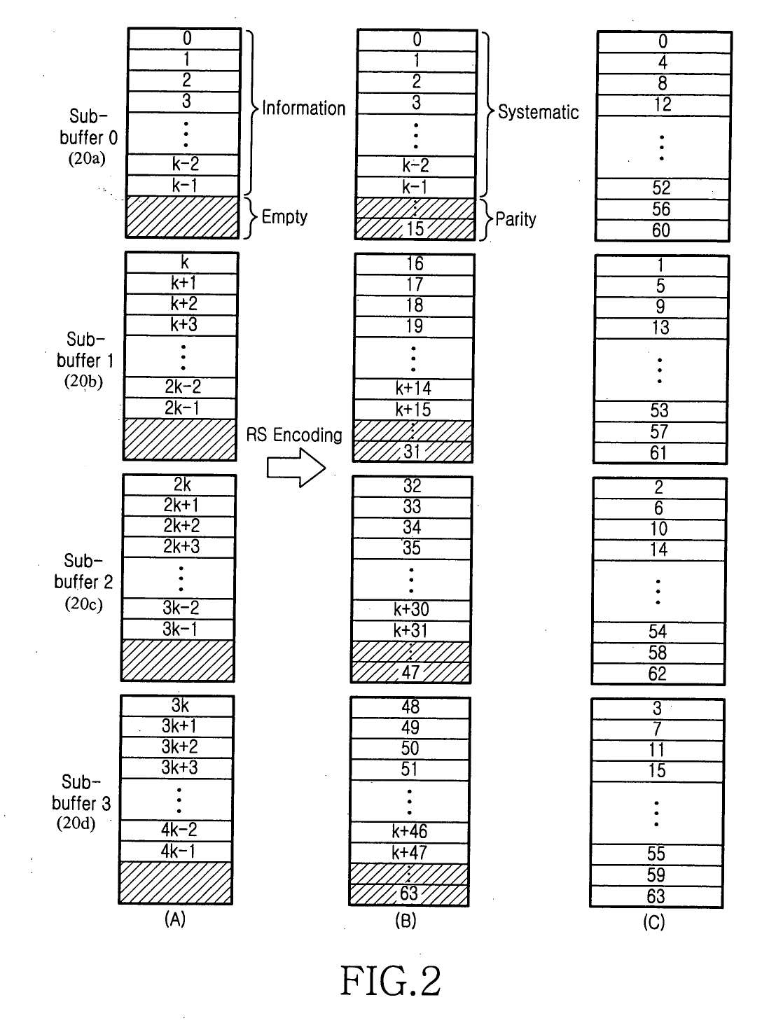

### DETAILED DESCRIPTION OF EXEMPLARY EMBODIMENT

Several exemplary embodiments of the present invention will now be described in detail with reference to the annexed drawings. In the following description, a detailed description of known functions and configurations incorporated herein has been omitted for the sake of conciseness.

The embodiments of the present invention relate to the physical channel specifications used in a CDMA2000 1x Rev. D standard, which is a synchronous CDMA mobile communication standard, and when applied to a buffer for Reed-Solomon (RS) codes used for Broadcast/Multicast Service (BCMCS). The embodiments of present invention improve the efficiency of a receiver by removing unnecessary data copying processes by placing an output buffer for temporarily storing RS-decoded data in a deinterleaver buffer. It will be understood by those skilled in the art that this technology is not restricted to the CDMA2000 1x Rev. D system, which is a synchronous CDMA system, but can be applied to an HRPD Rev. A system, which is another synchronous CDMA system, having a buffer for BSMCS.

The embodiments of the present invention provide a method using one deinterleaver table and another method using two deinterleaver tables. With reference to the accompanying drawings, a description of the embodiment using one deinterleaver table will now be made with reference to two separate operations: a first operation of a deinterleaver buffer with a 61-frame size in which an output buffer is not considered and a second operation of a deinterleaver buffer with a 62-frame size in which the output buffer is considered.

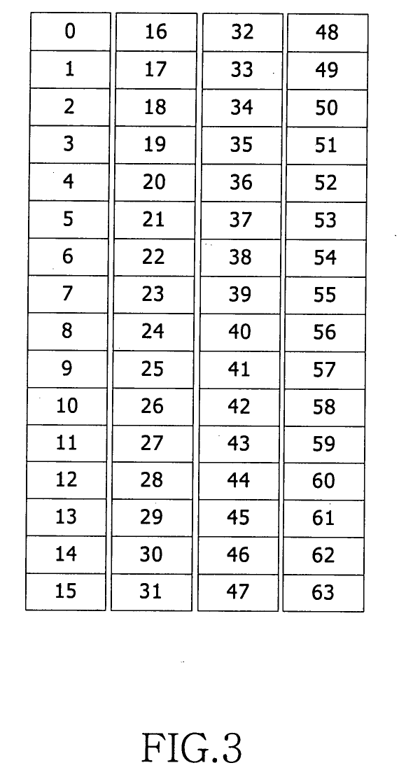

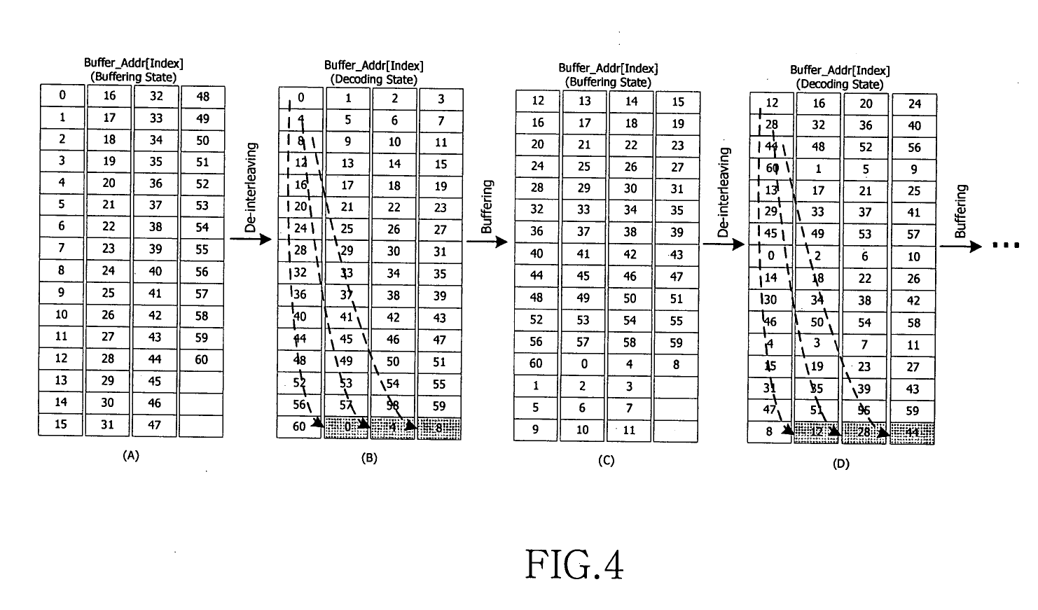

FIG. 3 is a diagram illustrating indexes representing 64 frames in a mobile communication system according to an embodiment of the present invention, and FIG. 4 is a diagram illustrating an exemplary method of deinterleaving data stored in a buffer in a mobile communication system according to an embodiment of the present invention. Specifically, FIG. 4 illustrates an operation of a deinterleaver buffer with a 61-frame size in which an output buffer is not considered.

Referring to FIGS. 3 and 4, a deinterleaver buffer is actually created using 61 buffers in a broadcast system, and ‘Buffer_Addr[ ]’ is a value actually representing a buffer with a 61-frame size. For example, for index=14, Buffer_Addr[14]=52 indicates that a 15^{th} reception frame is actually stored in a 53^{rd} position of the deinterleaver buffer.

If data is stored in the buffer in regular order according to buffer indexes as shown in (A) of FIG. 4, the data is deinterleaved as shown in (B) of FIG. 4 to RS-decode the stored data. After the deinterleaving, an RS decoder decodes the frames stored in index #0 to index #15. To perform a first RS decoding operation in this manner, a total of 61 buffers are only required.

After the decoding process is performed, a frame with an index #0 is transferred upward to a host, emptying one buffer, and a 62^{nd} reception frame is stored in the empty buffer. This operation is represented by the leftmost dotted line in (B) of FIG. 4.

Thereafter, RS decoding for a second sub-buffer is performed, and in the same manner, 63^{rd} and 64^{th} frames are received and RS decoding is performed thereon. As a result, one buffer is emptied every frame, and a new data frame is stored in the empty buffer. This process is repeated, filling the reception buffer. A reception buffer filled through this process is shown in (C) of FIG. 4. The succeeding operation is performed based on the foregoing principle, and the result is deinterleaved as shown in (D) of FIG. 4. Likewise, the succeeding operation is repeated in the same principle.

In this manner, a deinterleaved signal with a 64-frame size can be decoded using a buffer with a 61-frame size. However, when an output buffer for temporarily storing data is needed to store data for the time required by the host for reading the data, the decoded data is delivered to the host not directly but via the output buffer. In this case, data is copied and delivered to the output buffer every frame. The copying operation to the output buffer can be avoided through management of a buffer with a 62-frame size. That is, the output buffer is included in the deinterleaver buffer. With reference to the accompanying drawings, a description will now be made of an embodiment of a method of the present invention for managing a buffer with a 62-frame size.

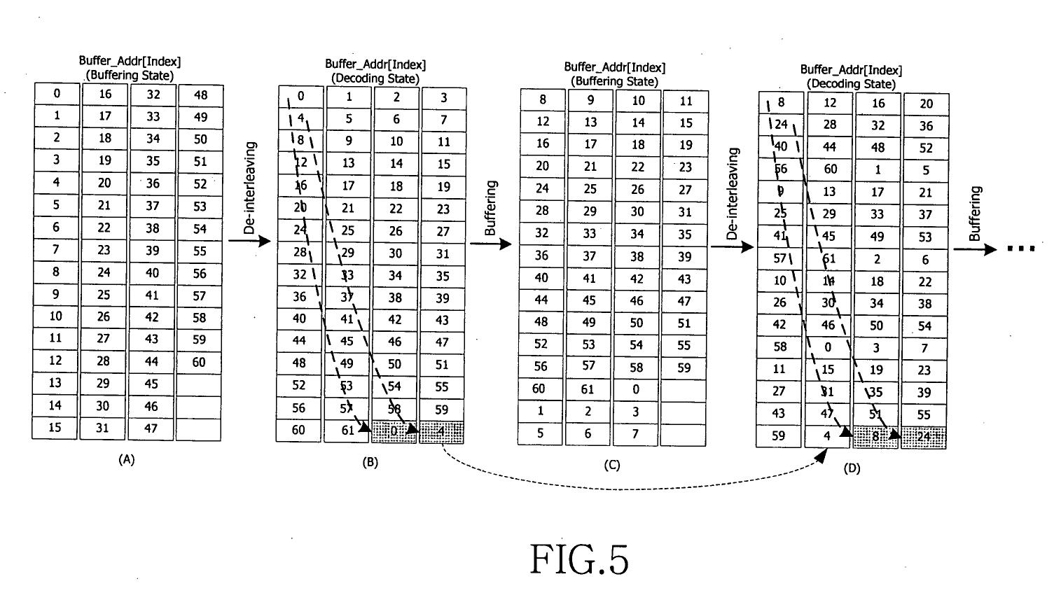

FIG. 5 is a diagram illustrating another exemplary method of deinterleaving data stored in a buffer in a mobile communication system according to an embodiment of the present invention. Specifically, FIG. 5 illustrates an operation of a deinterleaver buffer with a 62-frame size in which an output buffer is considered.

If data is stored in the buffer in regular order as shown in (A) of FIG. 5, the data is deinterleaved as shown in (B) of FIG. 5 to RS-decode the stored data. After the deinterleaving, an RS decoder decodes frames stored in index #0 through index #15. To perform a first RS decoding operation in this manner, a total of 61 buffers are required only.

After the decoding process is performed, a frame in index #0 is transferred upward to a host, emptying one buffer. However, in order to secure a time required by the host for fully reading data of the decoded 0^{th} frame, a 62^{nd} reception frame is stored in a 62^{nd} buffer (Buffer_Addr[61]=61) while the index #0 is read by the host, as shown in (B) of FIG. 5. Thereafter, RS decoding for a second sub-buffer is performed, and a 63^{rd} reception frame is stored in the empty buffer with index #0. This operation is represented by the leftmost dotted line in (B) of FIG. 5.

In this manner, if a 64^{th} frame is received, an RS decoding operation is performed thereon. A process in which one buffer prepares to be read by the host (the buffer serves as an output buffer), another buffer is empted, and new frame data is stored in the empty position (buffer), is repeated every frame. With the repetition of the process, the reception buffer is filled as shown in (C) of FIG. 5. Herein, an arrow with a dotted line connecting (B) to (D) of FIG. 5 represents an address of the buffer, remaining after deinterleaving from (C) to (D).

The succeeding operation is performed based on the same principle, and the result is deinterleaved as shown in (D) of FIG. 5. Likewise, the succeeding operation is repeated in the foregoing principle.

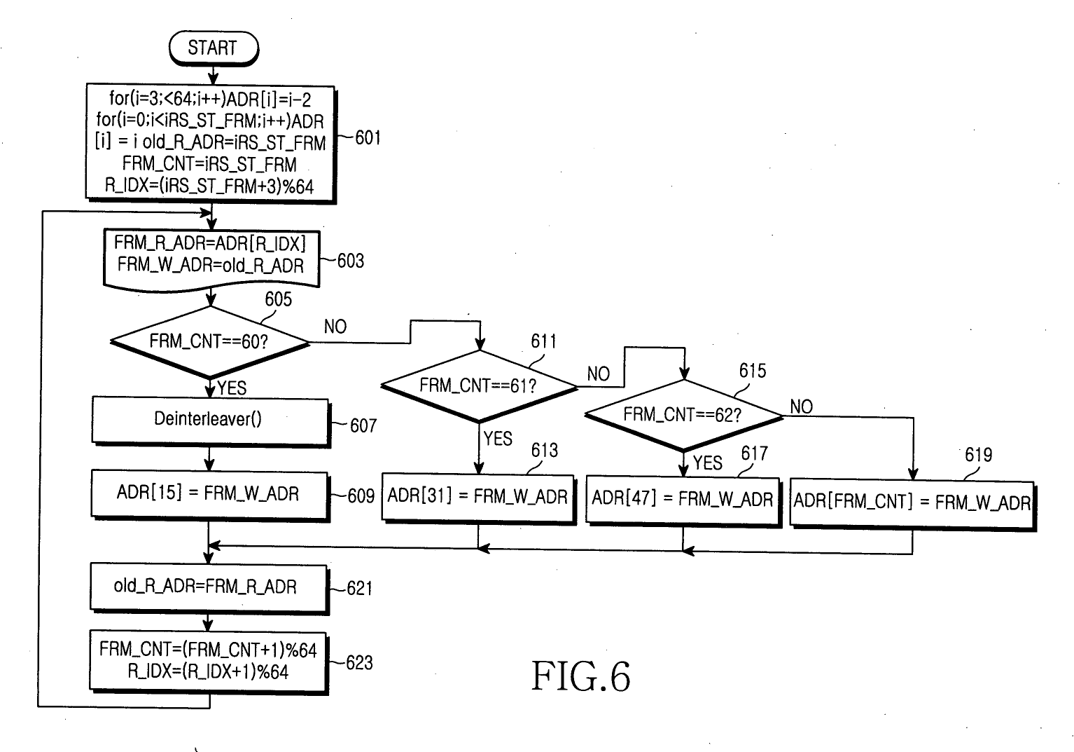

With reference to the accompanying flowchart of FIG. 6, a description will now be made of an operation of a deinterleaver buffer.

FIG. 6 is a flowchart illustrating an operation of managing a deinterleaver buffer according to an embodiment of the present invention.

In step 601, the deinterleaver performs an initialization. The deinterleaver initializes an address (ADR) table when a first input to the buffer is an (iRS_ST_FRM)^{th} frame, initializes a first buffer input address (old_R_ADR=iRS_ST_FRM) when a first input to the buffer is an (iRS_ST_FRM)^{th} frame, initializes an input frame counter (FRM_CNT=iRS_ST_FRM) when a first input to the buffer is an (iRS_ST_FRM)^{th} frame, and initializes an output frame counter (R_IDX=(iRS_ST_FRM+3)%64) such that when a first input to the buffer is an (iRS_ST_FRM)^{th} frame, a one-frame time delay can occur between an output address and an input address.

In step 603, the deinterleaver sets a buffer address FRM_R_ADR that the host must read, to a buffer address Buffer_Addr[ ] shown in FIG. 5 (FRM_R_ADR=ADR[R_IDX]), and sets a buffer address FRM_W_ADR where data must be input to a corresponding buffer, to a read address old_R_ADR for a one-frame time delay.

Thereafter, the deinterleaver determines in step 605 whether a frame counter FRM_CNT is 60 (FRM_CNT=60). If FRM_CNT=60, the deinterleaver sets a deinterleaver function Deinterleaver( ) in step 607, and sets an address ADR[15] of a 16^{th} buffer to a buffer address FRM_W_ADR where data must be input to a corresponding buffer, in step 609.

However, if it is determined in step 605 that FRM_CNT≠60, the deinterleaver determines in step 611 whether FRM_CNT=61. If FRM_CNT=61, the deinterleaver sets an address ADR[31] of a 32^{nd} buffer to a buffer address FRM_W_ADR where data must be input to a corresponding buffer, in step 613. Otherwise, if FRM_CNT≠61, the deinterleaver determines in step 615 whether FRM_CNT=62. If FRM_CNT=62, the deinterleaver sets an address ADR[47] of a 48^{th} buffer to a buffer address FRM_W_ADR where data must be input to a corresponding buffer, in step 617. Otherwise, if FRM_CNT≠62, the deinterleaver sets a buffer address for a frame counter to a buffer address FRM_W_ADR where data must be input to a corresponding buffer, in step 619. After the steps 609, 613, 617, and 619, the deinterleaver proceeds to step 621.

In step 621, the deinterleaver sets a buffer address FRM_W_ADR where data must be input to a corresponding buffer to a buffer address FRM_R_ADR where the host must read data. Thereafter, in step 623, the deinterleaver sets data frame indexes R_IDX that the frame counter and the host must read, to ‘FRM_CNT=(FRM_CNT+1)%64)’ and ‘R_IDX=(R_IDX+1)%64’, respectively, and then returns to step 603.

A description will now be made of a method for converting a buffer address table by the deinterleaver according to an embodiment of the present invention.

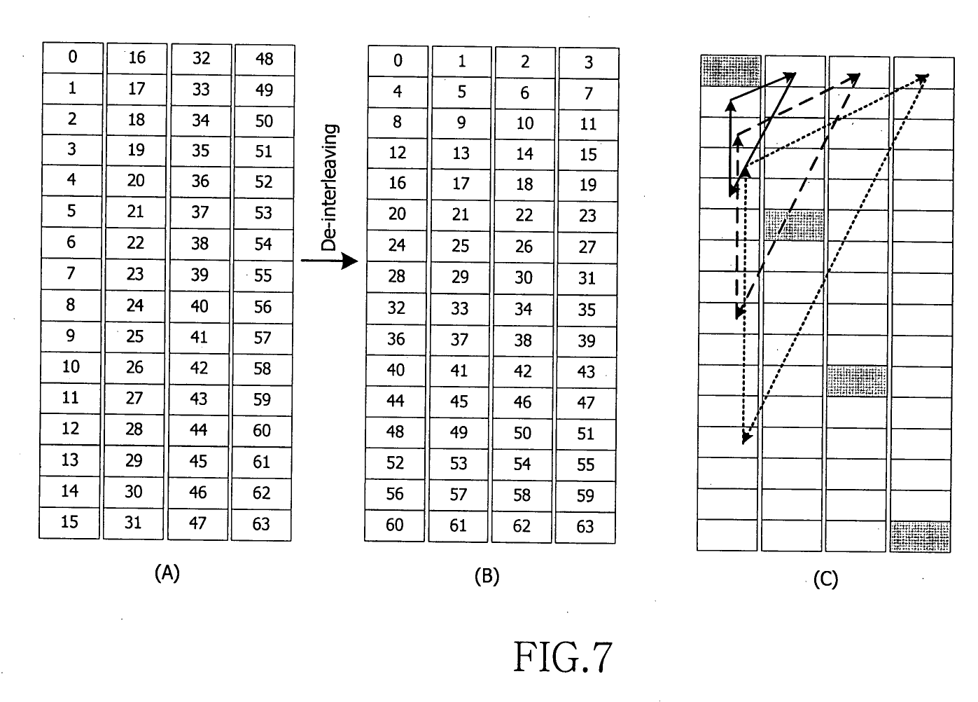

FIG. 7 is a diagram illustrating the conversion of a buffer address table by a deinterleaver according to the first embodiment of the present invention.

The deinterleaver can be expressed as
g=└i/4┘+(16×i)mod64, i=0, . . . , 63 Equation (1)
where i denotes an index before permutation (or shuffling), and g denotes an index after permutation.

Referring to FIG. 7, (A) represents data stored in the buffer before deinterleaving, and (B) represents data stored in the buffer after deinterleaving. A permutation process for deinterleaving from (A) to (B) is shown in (C) of FIG. 7. Herein, positions 0, 21, 42 and 63 remain unchanged even after the table conversion. That is, the positions 0, 21, 42 and 63 satisfy the following conditions.
imod64=└i/4┘+(16×i)mod64, i=0, . . . , 63 Equation (2)

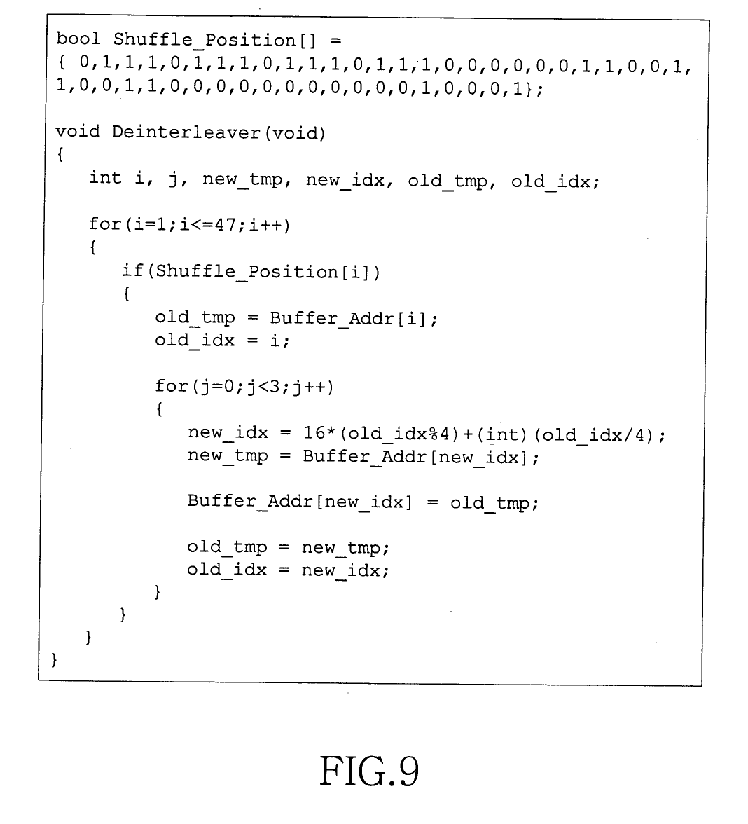

The other positions that do not satisfy the conditions of Equation (2) undergo permutation in the form of a triangle shown in (C) of FIG. 7. For example, ‘2’ in (A) is shifted from a position in a 3^{rd} row and a 1^{st} column to a position in a 1^{st} row and a 3^{rd} column in (B) after permutation. In this manner, permutation is achieved in the order of ‘2→32→8→2’. The permutation operation is performed along triangles represented by dotted lines in (C). All of 60 positions except for the positions 0, 21, 42 and 63 hatched in (C) undergo triangular permutation, and the possible number of triangular permutations is 60/3=20. A deinterleaver implemented by the triangular permutation may be executed in the computer by the C-language code shown in FIG. 9.

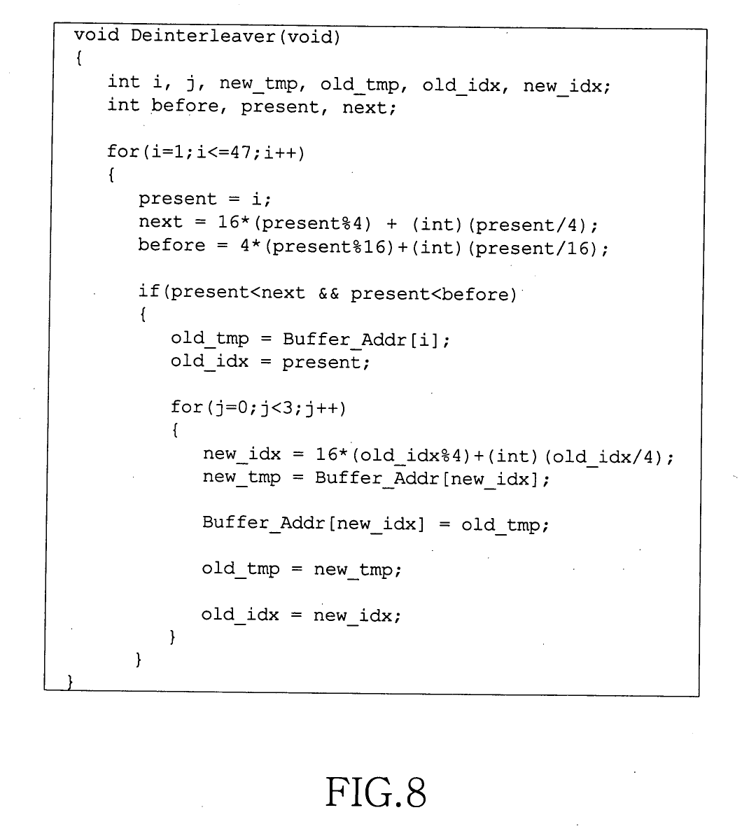

In the C-language source code shown in FIG. 8, the code routine ‘if (present<next && present<before)’ is for preventing duplication of the triangular permutation. For example, the permutation of ‘2→32→8→2’ should be achieved once. However, if the permutation of ‘32→8→2→32’ is performed at the position ‘32’ and permutation of ‘8→2→32→8’ is performed at the position ‘8’ repeatedly after permutation of 2→32→8→2 is performed at the position ‘2’, the desired permutation cannot be achieved. Therefore, ‘if (present<next && present<before)’ is given to prevent duplicate permutations of ‘32→8→2→32’ and ‘8→2→32→8’.

Because there is no permutation process after the position ‘47’ for this reason, the routine ‘for (i=0: i<=47; i++)’ is given so that the entire repetition loop is limited to 47. In order not to calculate ‘next’ and ‘before’ each time for prevention of duplication, it is possible to record a position ‘i’ where ‘if (present<next && present<before)’ passes and executes a ‘for’ sentence only at the position. In the case of BCMCS, ‘i’ passing an ‘if’ sentence can be expressed as
iε{1, 2, 3, 5, 6, 7, 9, 10, 11, 13, 14, 15, 22, 23, 26, 27, 30, 31, 43, 47} Equation (3)

A C code for a deinterleaver implemented using Equation (3) is shown in FIG. 9. The C code can efficiently implement the deinterleaver as it does not calculate ‘next’ and ‘before’. ‘Shuffle[ ]’ shown in FIG. 9 is a 1-bit array wherein a position of Equation (3) is stored as ‘0’ and the other positions are stored as ‘0’. Therefore, the same result can be obtained by performing the permutation operation on only the ‘i’ shown in FIG. 8.

The buffer management method has been described with reference to the first embodiment in which one deinterleaver table is used. Next, the buffer management method will be described with reference to a second embodiment in which two deinterleaver tables are used.

For convenience, a unit of a 64-frame buffer comprised of 4 sub-buffers will be referred to as a super frame. In addition, the two tables will be referred to as a table A and a table B, respectively. The two deinterleaver tables are independently used as a table for even-numbered input super frames and a table for odd-numbered input super frames. For example, if the table A is used for a deinterleaver operation of an n^{th} super frame, the table B is used for a deinterleaver operation of an (n+1)^{th} super frame.

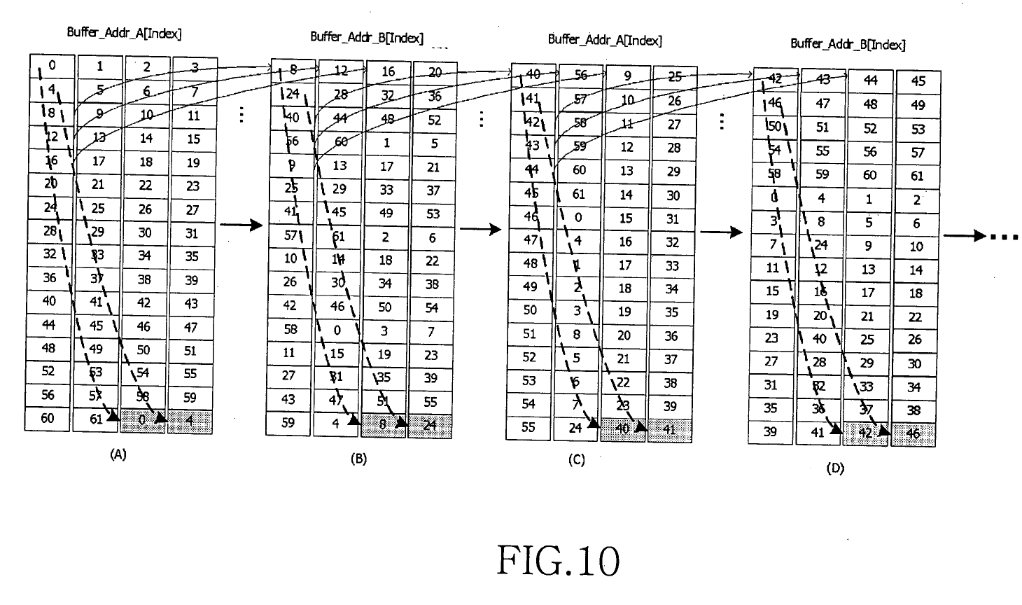

FIG. 10 is a diagram illustrating an example of a buffer with a 62-frame size in a deinterleaver for a broadcast service system according to a second embodiment of the present invention. In FIG. 10, (A) and (C) represent the buffering state of Buffer_Addr_A[ ], and (B) and (D) represent a decoding state of Buffer_Addr_B[ ].

Referring to FIG. 10, the buffer tables Buffer_Addr_A[ ] and Buffer_Addr B[ ] are alternately used. Upon receiving each frame, a receiver performs a deinterleaving operation on the received frame, generating Buffer_Addr_x[ ]. That is, as shown in FIG. 3, the receiver stores a first frame in the position with an index #0, a second frame in the position with an index #16, and a third frame in the position with an index #32. This can be expressed as
Index=16×(frm_{—}cnt %4)+└frm_{—}cnt/4┘ Equation (4)

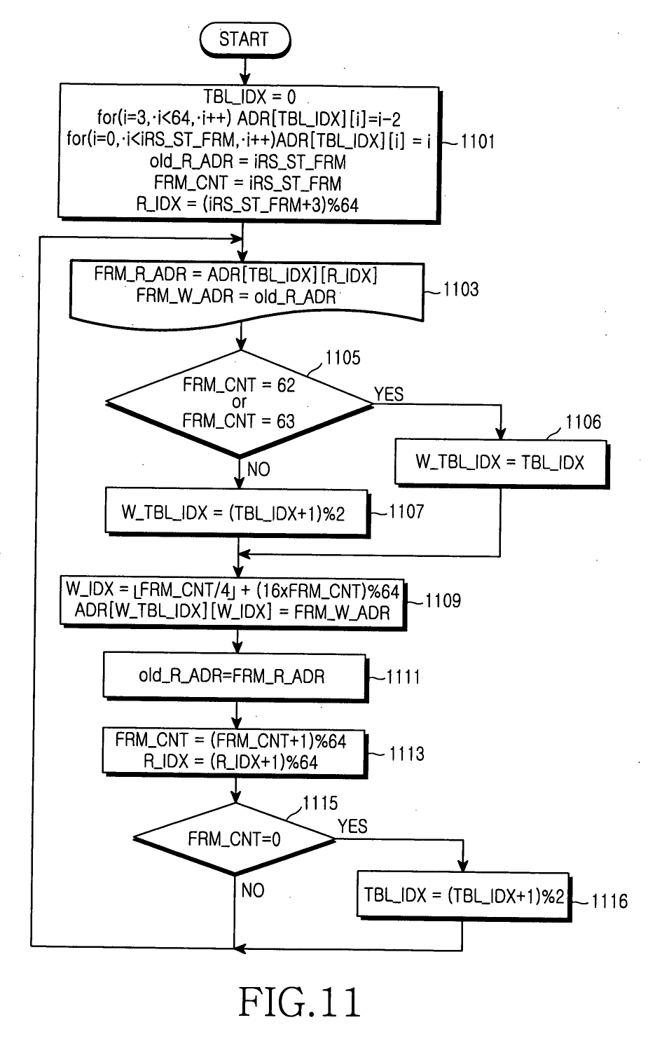

If frame data tables are created as shown in FIG. 10 using Equation (4), buffers with an index=0 through 15 are decoded intact for a first sub-buffer. In the same manner, buffers with an index=16 through 31, buffers with an index=32 through 47, and buffers with an index=48 through 63 are decoded intact for a second sub-buffer, a third sub-buffer, and a fourth sub-buffer, respectively. It is shown in FIG. 10 that for indexes #47 and #63, when buffers with indexes #0 and #4 for each of their tables are emptied, data is stored in the empty buffers, as shown by arrows with dotted lines. In the other region, as shown in FIG. 10, an empty buffer region is found not from its own table but from the other table, corresponding information is written in that position, and information on the position written in its own buffer is stored its own table. This operation will now be described with reference to the flowchart shown in FIG. 11.

In step 1101, a deinterleaver performs an initialization. The deinterleaver selects a table to be used first, and then initializes the selected table when a first input to a buffer is an (iRS_ST_FRM)^{th} frame, initializes a first buffer input address (old_R_ADR=iRS_ST_FRM) when a first input to the buffer is an (iRS_ST_FRM)^{th} frame, initializes an input frame counter (FRM_CNT=iRS_ST_FRM) when a first input to the buffer is an (iRS_ST_FRM)^{th} frame, and initializes an output frame counter (R_IDX=(iRS_ST_FRM+3)%64) such that when a first input to the buffer is an (iRS_ST_FRM)^{th} frame, a one-frame time delay can occur between an output address and an input address.

In step 1103, the deinterleaver sets a buffer address FRM_R_ADR that the host must read, to a buffer address Buffer_Addr_A[ ] (FRM_R_ADR=ADR[TBL_IDX][R_IDX]), and sets a buffer address FRM_W_ADR where data must be input to a corresponding buffer, to a read address old_R_ADR for a one-frame time delay.

In step 1105, the deinterleaver determines whether a frame counter value FRM_CNT is 62 (or 63) (FRM_CNT=62 or FRM_CNT=63). If this condition is satisfied, the deinterleaver sets a buffering table index W_TBL_IDX to a decoding table index TBL_IDX in step 1106, and then proceeds to step 1109. Otherwise, the deinterleaver sets the buffering table index W_TBL_IDX according to ‘(TBL_IDX+1)%2’ in step 1107.

In step 1109, the deinterleaver sets a frame index W_IDX to be written in a buffering table according to ‘└FRM_CNT/4┘+(16×FRM_CNT)%64’, and sets a buffer address ‘ADR[W_TBL_IDX][W_IDX])’ to a buffer address FRM_W_ADR where data should be input to a corresponding buffer.

In step 1111, the deinterleaver sets a read address old_R_ADR for a one-frame time delay to a buffer address FRM_R_ADR that the host must read. Thereafter, in step 1113, the deinterleaver sets the frame counter according to ‘(FRM_CNT+1)%64’, and sets a data frame index R_IDX that the host must read, according to ‘(R_IDX+1)%64’.

Thereafter, the deinterleaver determines in step 1115 whether the frame counter is 0 (FRM_CNT=0). If FRM_CNT=0, the deinterleaver sets a decoding table index TBL_IDX according to ‘(TBL_IDX+1)%2’ in step 1116, and then returns to step 1103.

As can be understood from the foregoing description, the method and apparatus according to embodiments of the present invention can efficiently manage a deinterleaver buffer by designing the deinterleaver buffer such that a size of the deinterleaver buffer is less than a size of a block interleaver used in a transmitter.

In addition, the novel deinterleaver buffer management method and apparatus avoids an unnecessary data copying process by placing an output buffer for providing the time required by a host to read decoded data in the deinterleaver buffer, thereby contributing to a reduction in required memory capacity and power consumption of a mobile station.

While the invention has been shown and described with reference to a certain preferred embodiment thereof, it will be understood by those skilled in the art that various changes in form and details may be made therein without departing from the spirit and scope of the invention as defined by the appended claims.

1. A method for managing a deinterleaver buffer using one deinterleaver table in a mobile communication system, the method comprising the steps of:
making the deinterleaver buffer in a size smaller than a size of the block interleaver;
receiving data interleaved in a predetermined size, and storing frames of the data in the deinterleaver buffer;
deinterleaving the frames of the data stored in the deinterleaver buffer; and
separately decoding the deinterleaved frames in sub-buffers of the deinterleaver buffer, delivering the decoded frames to a host, and storing new frames in sub-buffers emptied due to the delivery of the decoded frames to the host;
wherein a size of the deinterleaver buffer is smaller than a size of the block interleaver.

2. The method of claim 1, wherein the deinterleaver buffer is divided into 4 sub-buffers, and includes a buffer with a 61-frame size in which a time required for delivering the data deinterleaved in a 64-frame size to the host for decoding is not considered.

3. The method of claim 1, wherein the deinterleaving step comprises the step of:
permuting indexes of the sub-buffers in the deinterleaver table by triangular permutation.

4. A method for managing a deinterleaver buffer using one deinterleaver table in a mobile communication system, the method comprising the steps of:
making the deinterleaver buffer in a size smaller than a size of the block interleaver;
receiving data interleaved in a predetermined size, and storing frames of the data in the deinterleaver buffer in regular order;
deinterleaving the frames of the data stored in the deinterleaver buffer;
separately decoding the deinterleaved frames in sub-buffers of the deinterleaver buffer; and
preparing to deliver a decoded frame in a position with a first buffer index to a host every frame, delivering a decoded frame in a position with a second buffer index to the host, and storing a new frame in a sub-buffer emptied due to the delivery of the decoded frame in the position with the second buffer index;
wherein a size of the deinterleaver buffer is smaller than a size of the block interleaver.

5. The method of claim 4, wherein the deinterleaver buffer is divided into 4 sub-buffers, and includes a buffer with a 62-frame size in which a time required for delivering the data deinterleaved in a 64-frame size to the host for decoding is considered.

6. The method of claim 4, wherein the deinterleaving step comprises the step of:
permuting indexes of the sub-buffers in the deinterleaver table by triangular permutation.

7. A method for managing a deinterleaver buffer using two deinterleaver tables in a mobile communication system, the method comprising the steps of:
making the deinterleaver buffer in a size smaller than a size of the block interleaver;
receiving odd-numbered data interleaved in a predetermined size, and storing frames of the received odd-numbered data in the deinterleaver buffer in a first deinterleaver table;
receiving even-numbered data interleaved in a predetermined size, and storing frames of the received even-numbered data in the deinterleaver buffer in a second deinterleaver table;
deinterleaving the frames of the data stored in the deinterleaver buffer;
separately decoding the deinterleaved frames in sub-buffers of the deinterleaver buffer;
preparing to deliver a decoded frame in a position with a first buffer index to a host every frame, delivering a decoded frame in a position with a second buffer index to the host, and storing a new frame in a sub-buffer emptied due to the delivery of the decoded frame in the position with the second buffer index; and
detecting an empty first buffer index from the second deinterleaver table in the second buffer region, writing information on the empty buffer index in a position of its buffer, and storing the position information in its respective deinterleaver table;
wherein a size of the deinterleaver buffer is smaller than a size of the block interleaver.

8. The method of claim 7, wherein the deinterleaver buffer is divided into 4 sub-buffers, and includes a buffer with a 62-frame size in which a time required for delivering the data deinterleaved in a 64-frame size to the host for decoding is considered.

9. The method of claim 7, wherein the deinterleaving step comprises the step of:
permuting indexes of the sub-buffers in the deinterleaver table by triangular permutation.

10. An apparatus for managing a deinterleaver buffer in a mobile communication system, the apparatus comprising:
a deinterleaver for receiving data interleaved in a predetermined size, for storing frames of the data in the deinterleaver buffer in regular order, and for deinterleaving frames of the data stored in the deinterleaver buffer; and
a decoder for separately decoding frames in sub-buffers of the deinterleaver buffer;
wherein a size of the deinterleaver buffer is smaller than a size of the block interleaver, the deinterleaver delivers the decoded frames to a host, and stores new frames in the sub-buffers emptied due to the delivery of the decoded frames.

11. The apparatus of claim 10, wherein the deinterleaver buffer is divided into 4 sub-buffers, and includes a buffer with a 61 or 62-frame size in which a time required for delivering the data deinterleaved in a 64-frame size to the host for decoding is not considered.

12. The apparatus of claim 10, wherein the deinterleaver performs deinterleaving by permuting indexes of the sub-buffers in the deinterleaver table by triangular permutation.
